(19) United States
(12) Patent Application Publication
(10) Pub. No.: US 2008/0074930 A1
(43) Pub. Date: Mar. 27, 2008

(54) SEMICONDUCTOR MEMORY DEVICE

(75) Inventor: Kazushige KANDA, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/859,315

(22) Filed: Sep. 21, 2007

(30) Foreign Application Priority Data
Sep. 22, 2006 (JP) 2006-256684

(51) Int. Cl. G11C 11/34

(52) U.S. Cl. 365/185.17

(57) ABSTRACT

This semiconductor memory device has plural semiconductor chips inputting control signals from commonly-connected I/O pads and control pads. The semiconductor chip comprises a self-address storing unit storing a self-chip address showing its own address, a judgment unit comparing the self-chip address with a selected address provided from outside via the I/O pads to judge a match thereof, and a control signal setting unit setting the control signal valid or invalid according to the judgment of the match.

### CROSS REFERENCE TO RELATED APPLICATIONS

This application is based on and claims the benefit of priority from prior Japanese Patent Application No. 2006-256684, filed on Sep. 22, 2006, the entire contents of which are incorporated herein by reference.

### BACKGROUND OF THE INVENTION

1. Field of the Invention

The present invention relates to a semiconductor memory device with stacked memory chips connected by a through via (a through hole).

2. Description of the Related Art

A semiconductor memory device is provided with a larger capacity in recent years. Accordingly, some semiconductor memory devices are employed as auxiliary memory devices instead of hard disk drives. Especially, a NAND-type EEPROM comprising NAND cells with serially-connected memory cells is suitable for high integration. For this reason, it is widely used for auxiliary memory devices used in portable terminal devices such as cellular phones, and for memory cards.

Moreover, in such a semiconductor memory device, plural memory chips are stacked inside a package. Moreover, a through via is formed to penetrate the stacked memory chips from the top to the bottom to commonly connect the pads of all the stacked memory chips. Thereby, semiconductor memory device may be provided with a further larger capacity. Such a semiconductor device is disclosed in JP 2005-209814 A.

However, this semiconductor memory device provides a chip-select pads at the top of the commonly-connected memory chips. The memory chip to be operated may be chosen by inputting a chip selection signal. For this reason, a selection signal must be input from “n” pieces of chip-select pads to chose one out of “2ⁿ” pieces of the memory chips. Therefore, as the number of the stacked memory chips becomes larger, the number of the selecting pads formed on top of the stacked memory chips increases. This makes it difficult to miniaturize the memory chip.

### SUMMARY OF THE INVENTION

In one aspect of the present invention the semiconductor memory device may comprise a plurality of semiconductor chips with commonly-connected I/O pads and control pads for inputting a control signal. The semiconductor chip comprises: a self-address storing unit storing a self-chip address showing its own address; a judgment unit comparing the self-chip address with a selected address provided from outside via the I/O pads to judge a match thereof; and a control signal setting unit setting the control signal valid or invalid according to the judgment of the match.

### BRIEF DESCRIPTION OF THE DRAWINGS

FIG. 1 is a sectional view showing a structure of a NAND type flash memory according to the first embodiment of the present invention.

FIG. 2 is a plan of the memory shown in FIG. 1.

FIG. 3 is a block diagram showing an electric structure of the stacked memory chips 2.

FIG. 4 is a block diagram showing the structure of the pads 3 in detail, and connections between the pads 3 and the internal circuits in the memory chip 2 in detail.

FIG. 5 exemplifies detailed structures of the buffers 25-30.

FIG. 6 is a block diagram exemplifying a structure of the chip address comparator 24.

FIG. 7 is a timing chart of the memory according to the first embodiment.

FIG. 8 is a timing chart that shows an operation of each of the memory chip 2.

FIG. 9 is a block diagram showing the detailed structure of the pads 3 provided in the memory according to the second embodiment, and connection between the pads 3 and the internal circuits in the memory chip 2 in detail.

FIG. 10 is a timing chart of the memory according to the second embodiment.

FIG. 11 is a plan view showing the uppermost memory chip 2B provided in the memory according to the third embodiment.

FIG. 12 is a block diagram showing the electric structure of the memory chip provided in the memory according to the third embodiment.

FIG. 13 is a circuit diagram exemplifying a structure of the CE buffer 26B.

FIG. 14 is a sectional view showing the structure of the memory according to the fourth embodiment of the present invention.

FIG. 15 is a plan view showing the uppermost memory chip in the memory according to the fourth embodiment.

### DETAILED DESCRIPTION OF THE EMBODIMENTS

The embodiments of the present invention will be described with reference to drawings attached herein.

### First Embodiment

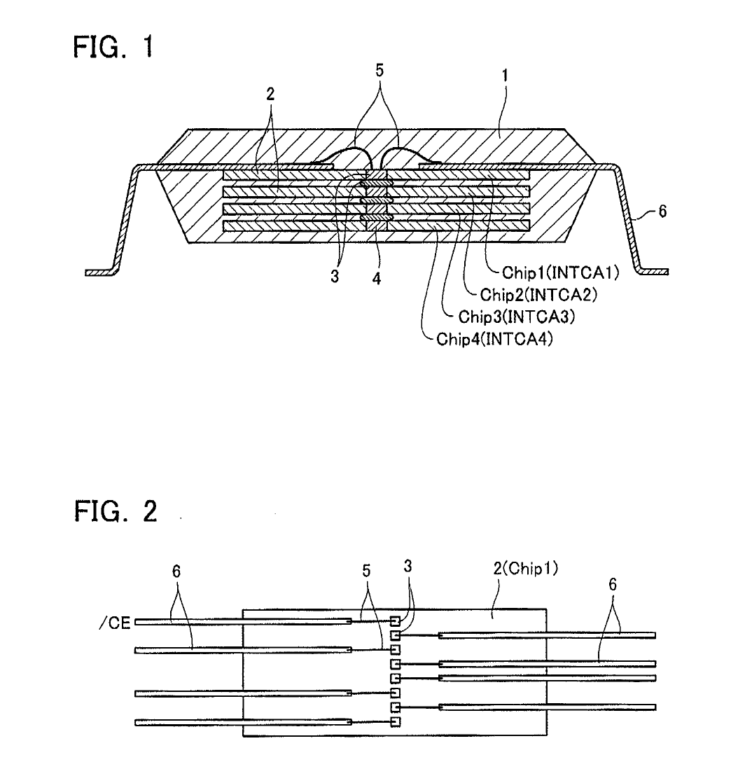

FIG. 1 is a sectional view showing a structure of a NAND type flash memory (hereafter referred to as a memory) according to a first embodiment of the present invention. FIG. 2 is a plan view of the memory shown in FIG. 1.

This NAND type flash memory comprises plural memory chips 2 stacked inside a package 1 formed of resin or the like. The stacked memory chips 2 are defined as Chip1, Chip2, Chip3, and Chip4 from the top, respectively.

Each of the stacked memory chips 2 has pads 3 for receiving and transmitting signals from and to outside of the memory chips 2. The pads 3 are formed at the center of the chips 3 in the planar direction.

The pads 3 provided in each of the stacked memory chips 2 are commonly connected by plural through holes 4. The holes 4 penetrate from the bottommost memory chip 2 to the uppermost memory chip 2 in a vertical direction.

As shown in FIG. 2, pads 3 formed in the uppermost chip Chip1 is connected via a wire 5 to the lead wire 6 arranged to project outside from the package 1. Thereby, the pads 3 in the chip Chip1 receives and transmits signals through the lead wire 6 from and to the exterior. The through holes 4 enables the pads 3 provided in each of the chips Chip1-Chip4 (memory chips 2) to receive and transmit signals from and to the lead wire 6.

As described later, these chips Chip 1-4 are given a self-chip address INTCA 1-4, respectively. The addresses INTCA 1-4 differs from one another. These chips Chip1-4 operate when the selected address EXTCA 1-4 input from the lead wire 6 matches their self-chip address INTCA 1-4.

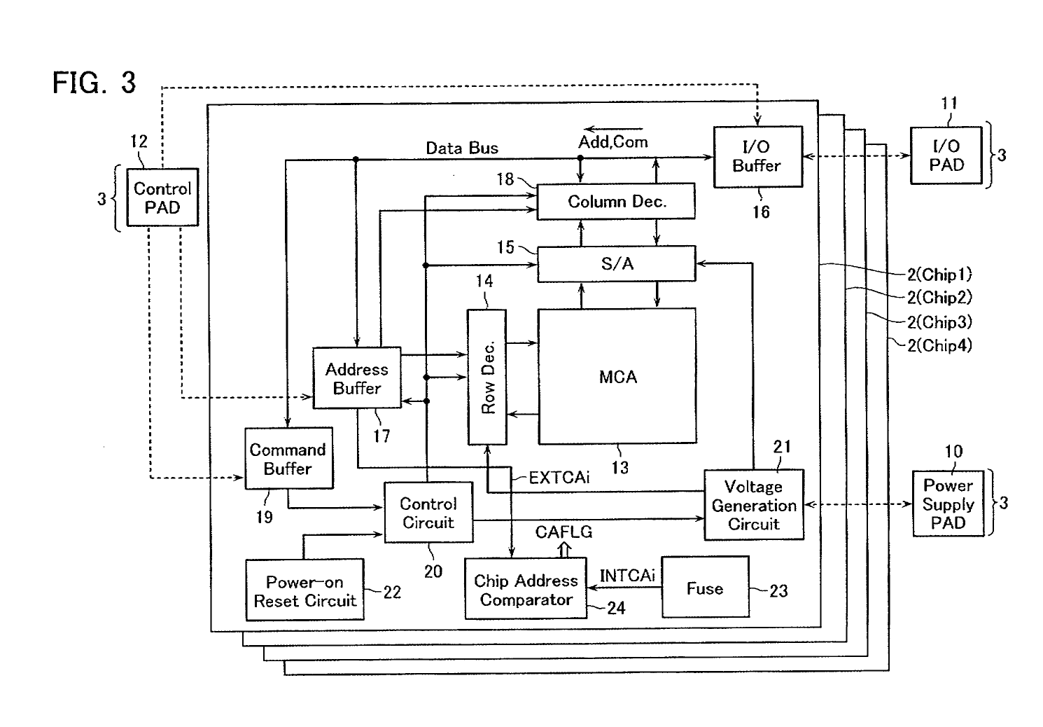

FIG. 3 is a block diagram showing an electric structure of each of the stacked memory chips 2.

The pads 3 comprises a power supply pad 10 for supplying a supply voltage, an I/O pad 11 for receiving and transmitting a data signal, and a control pad 12 for inputting a control signal. In addition to such the power supply pad 10, the I/O pad 11, and the control pad 12, the memory chip 2 is equipped with a memory cell array 13, a row decoder 14, a sense amplifier 15 and the like.

A memory cell array 13 includes plural bit lines and word lines. The electrically rewritable memory cells are arranged in matrix at the intersections of the bit lines and the word lines. The row decoder 14 selectively activates a word line and a selection gate line according to a row address. It includes a word-line driver and a selection gate line driver. The sense amplifier 15 is connected to the bit lines. The sense amplifier 15 detects and amplifies data.

Data transfer between the memory chip 2 and the I/O pad 11 is performed through the I/O buffer 16, a data bus, an address buffer 17, a column decoder 18 and a command buffer 19. The data input from the I/O pad 11 is taken into a sense amplifier 15.

Moreover, the address Add input through the I/O pad 11 is transmitted to the row decoder 14 and the column decoder 18 through the I/O buffer 16, a data bus, and an address buffer 17. Furthermore, the command Com input through the I/O pad 11 is transmitted to the control circuit 20 through the I/O buffer 16, a data bus, and a command buffer 19.

The control circuit 20 performs a control of data-write, data-read, and data-erase based on the input command Com. The voltage generation circuit 21 is controlled by the control circuit 20, and generates various internally-generated voltages required for write, read and erase. The voltage generation circuit 21 also includes a booster circuit to generate an internal voltage higher than the supply voltage supplied from the power supply pad 10.

A power-on reset circuit 22 detects a power-on in a memory chip 2, and makes the control circuit 20 to perform a reset operation. The self-chip address INTCAi is stored in a fuse 23. The chip Chip 1-4 is given an original self-chip address INTCAi.

A laser-fuse type fuse element or a nonvolatile-memory type fuse element may be used as a fuse 23 storing its own chip address INTCAi. The chip-address comparator 24 compares the selected chip address EXTCAi input from the address buffer 17, and the self-chip address INTCAi input from the fuse 23. It outputs an address flag signal CAFLG as a matching judgment signal to show whether they match or not.

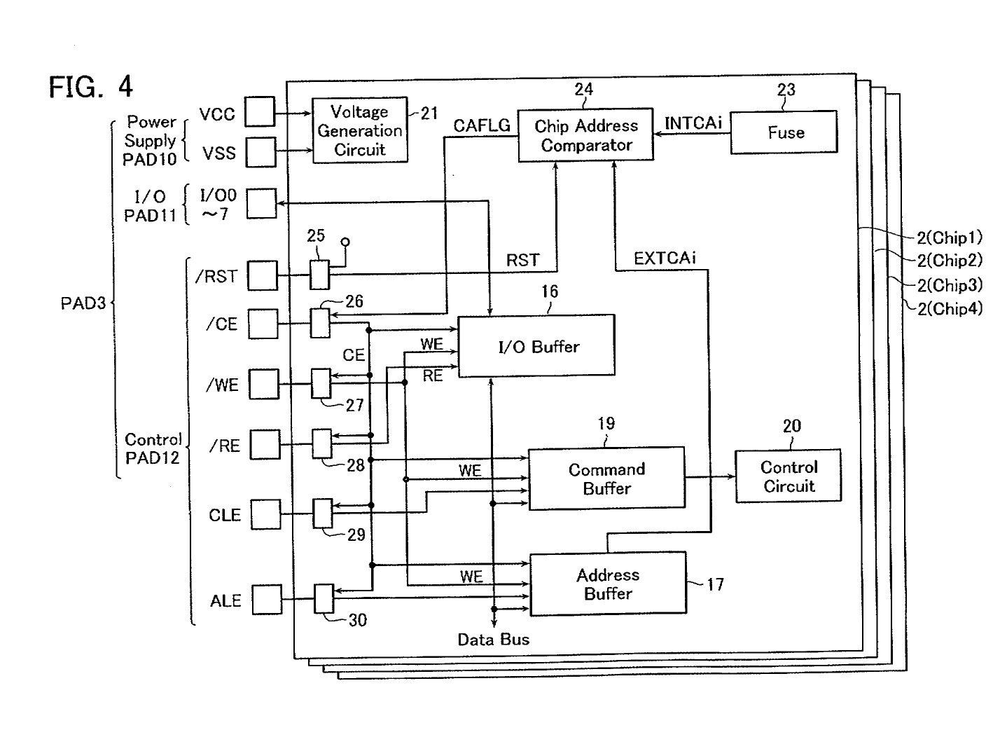

FIG. 4 is a block diagram showing the structure of the pads 3 in detail, and connections between the pads 3 and the internal circuits in the memory chip 2 in detail. The supply voltage VCC and the ground voltage VSS are input into two power supply pads 10, respectively. For example, the voltage required is supplied to the voltage generation circuit 21 or the like.

Eight-bit data I/O 0-7 are input into the I/O pads 11, for example. The data I/O 0-7 is fed into the I/O buffer 16. The control pads 12 comprise six pads 3, for example. Different control signals are input to the pads 3, respectively.

Here, the following control signals shall be input as an example:

(1) A reset signal /RST for resetting the memory chip 2 in a selectable state (selected and thus accessible) or a non-selectable state (not selected, thus not accessible), to be in a selectable state;

(2) a chip-enable signals /CE for setting a memory chip 2 accessible;

(3) a write-enable signal /WE for writing data in a memory chip 2;

(4) a read enable signal /RE for serially outputting data from the memory chip 2;

(5) a command latch enable signal CLE for inputting data I/O 0-7 as a command; and

(6) an address-latch-enable signal ALE for inputting data I/O 0-7 as an address.

Such signals that are input to the control pad 12 are output to an RST buffer 25, a CE buffer 26, a WE buffer 27, an RE buffer 28, a CLE buffer 29, and an ALE buffer 30, respectively. These buffers 25-30 are changed between an active state or an inactive state by a signal input to the buffer input terminal INBUFen. That is, each of the buffers 25-30 serves as a control signal setting unit for setting the control signal input thereto valid or invalid based on the signal from this buffer input terminal INBUFen.

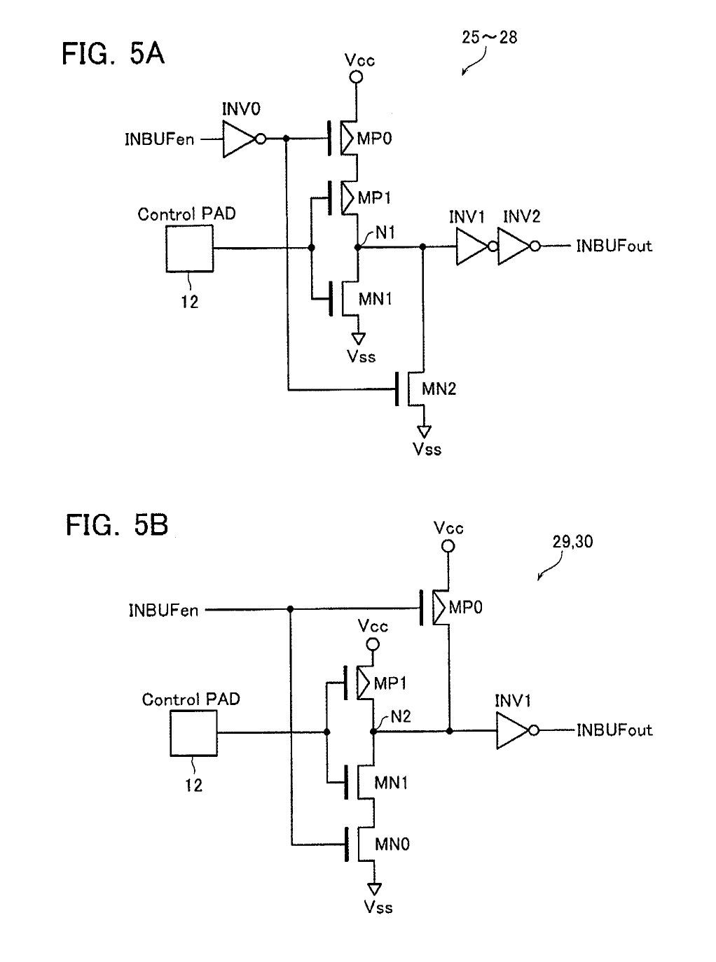

A structure of the RST buffer 25, the CE buffer 26, the WE buffer 27, and the RE buffer 28 is shown in FIG. 5A, for example. A structure of the CLE buffer 29 and the ALE buffer 30 is shown in FIG. 5B, for example.

As shown in FIG. 5A, P-type MOS transistors MP0, MP1 and N-type MOS transistors MN1 and MN2 may constitute buffers 25-28, for example. A P-type MOS transistor MP0 has a source connected to the supply voltage VCC. The buffer input terminal INBUFen is connected to its gate through an inverter INV0.

In addition, the signal input to the buffer input terminal INBUFen is always set as “H” in the RST buffer 25. On the other hand, in the CE buffer 26, an address flag signal CAFLG is input to the buffer input terminal INBUFen. Moreover, in the WE buffer 27 and the RE buffer 28, a chip-enable signal CE′ output from the CE buffer 26 is input to the buffer input terminal INBUFen, as described later.

The P-type MOS transistor MP1 has a source connected to a drain of the P-type MOS transistor MP0. It also has a gate given a control signal (a reset signal /RST, a chip-enable signal /CE, a write-enable signal WE, a read enable signal RE) from each control pad 12.

The N-type MOS transistor NM1 has a drain node N1 connected to a drain of the P-type MOS transistor MP1, a source connected to the ground voltage VSS, and a gate given the control signal from each control pad 12. When the control signal is “H”, the output of the node N1 is set to “L”. When the control signal is “L”, the output of the node N1 is “H”. That is, one MOS inverter INVc comprises the transistors MP1 and MN1.

The output from the drain of the N-type MOS transistor MN1 is connected to the buffer output terminal INBUFout through the inverters INV1 and INV2. The signal output from the buffer output terminal INBUFout in the RST buffer 25 is the reset signal RST. The signal output from the buffer output terminal INBUFout in the CE buffer 26 is the chip-enable signal CE′. The signal output from the buffer output terminal INBUFout in the WE buffer 27 is the write-enable signal WE. The signal output from the buffer output terminal INBUFout in the RE buffer 28 is the read enable signal RE.

The N-type MOS transistor MN2 has a source connected to the ground voltage VSS, and a gate given an inversion signal (/INBUFen) of the signal input to the buffer input terminal INBUFen through the inverter INV0. Since the buffers 25-28 are constituted as described above, the control signal input from each control pad 12 may be made valid when the signal input to the buffer input terminal INBUFen is “H”. Moreover, the control signal input from each control pad 12 may be made invalid when the signal input to the buffer input terminal INBUFen is “L”.

Moreover, as shown in FIG. 5B, the buffers 29 and 30 are equipped with P-type MOS transistors MP0, MP1, N-type MOS transistors MN0, MN1, for example.

The P-type MOS transistor MP0 has a source connected to the supply voltage VCC, a drain connected to the node N2, and a gate connected to the buffer input terminal INBUFen.

The P-type MOS transistor MP1 has a source connected to the supply voltage VCC, a drain connected to the node N2, and a gate given the control signal (ALE or CLE) from the control pad 12.

The N-type MOS transistor MN1 has a source connected to the ground voltage VSS through the N-type MOS transistor MN0, a drain connected to the node N2, and a gate given the control signal (ALE or CLE) from the control pad 12.

The N-type MOS transistor MN0 has a source connected to the ground voltage VSS, a drain connected to the source of the N-type MOS transistor MN1, and a gate connected to the buffer input terminal INBUFen.

Note that the P-type MOS transistor MP1 and the N-type MOS transistor MN1 constitute one inverter INVd. The node N2 is an output of this inverter INVd. The node N2 is connected to the buffer output terminal INBUFout through the inverter INV1.

As mentioned above, the buffers 29 and 30 may validate the control signal ALE and CLE input from each control pad 12 when the signal input to the buffer input terminal INBUFen is “H”. On the other hand, the buffers 29 and 30 may invalidate the control signal ALE and CLE input from each control pad 12 when the signal input to the buffer input terminal INBUFen is “L”.

Next, connections between the buffers 25-30 and the internal circuits in the memory chip 2 are further explained with reference to FIG. 4.

The RST buffer 25, receives a signal that is always “H” at the buffer input terminal INBUFen.

The RST buffer 25 reverses the reset signal /RST input from the control pad 12 with inverters (INVc, INV1, INV2), and outputs the reset signal RST to a chip-address comparator 24 from the buffer output-terminal INBUFout. The chip-address comparator 24 is configured to reset (make it “H”) the chip-address flag signal CAFLG when the reset signal RST input is “H”.

The CE buffer 26 receives an address flag signal CAFLG generated by the chip-address comparator 24 at the buffer input terminal INBUFen. As mentioned above, the address flag signal CAFLG is output as “H”, when the chip-address comparator 24 judges that the self-chip address INTCAi and the selected chip address EXTCAi coincide. When this address flag signal. CAFLG is “H”, the CE buffer 26 validates the chip-enable signal /CE input from the control pad 12. At the same time, the CE buffer 26 reverses the chip-enable signal /CE with the inverters (INVc, INV1, INV2), and outputs it to the WE buffer 27, the RE buffer 28, the CLE buffer 29, and the ALE buffer 30 as the chip-enable signal CE′.

This chip-enable signal CE′ is input to the buffer input terminal INBUFen of the WE buffer 27, the RE buffer 28, the CLE buffer 29, and the ALE buffer 30. When the chip-enable signal CE′ is “H”, the control signal (the write-enable signal WE, the read enable signal RE, the command latch enable signal CLE, and the address-latch-enable signal ALE) input to each of the buffers 27-30 is validated. On the other hand, when the chip-enable signal CE′ is “L”, the control signal input to each of the buffers 27-30 is invalidated.

The WE buffer 27 is connected to the I/O buffer 16, the command buffer 19, and the address buffer 17. When the chip-enable signal CE′ is “H”, the WE buffer 27 receives the write-enable signal /WE, input from the control pad 12 as an internal clock signal WE. That is, the write-enable signal WE is output to the I/O buffer 16, the command buffer 19, and the address buffer 17 from the buffer output-terminal INBUFout in the WE buffer 27.

The RE buffer 28 is connected to the I/O buffer 16. Thereby, the RE buffer 28 receives the read enable signal/RE as an internal clock signal RE. The read enable signal/RE is input from the control pad 12 when the chip-enable signal CE′ is “H”. That is, the read enable signal RE is output to the I/O buffer 16 from the buffer output-terminal INBUFout in the RE buffer 28.

The CLE buffer 29 is connected to the command buffer 19, and outputs the command latch enable signal CLE to the command buffer 19 when the chip-enable signal CE′ is “H”. The ALE buffer 30 is connected to the address buffer 17, and outputs address-latch-enable signal ALE to the address buffer 17 when the chip-enable signal CE′ is “H”.

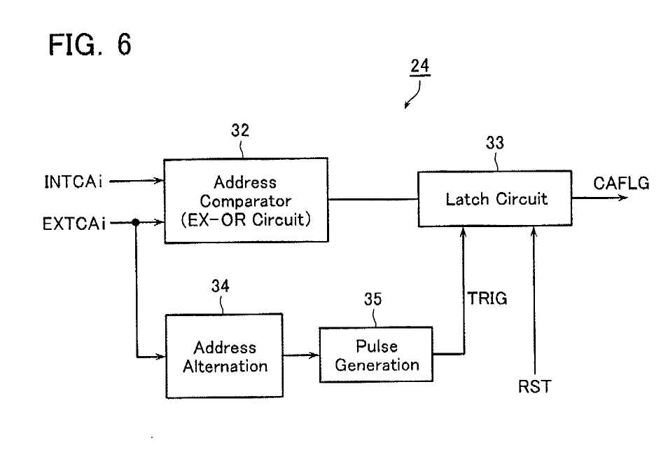

FIG. 6 is a block diagram showing an example of a structure of the chip-address comparator 24. This chip-address comparator 24 is equipped with an address comparator 32, a latch circuit 33, an address alteration detection unit 34, and a pulse generation unit 35.

The address comparator 32 is composed of an EXOR circuit, for example. The address comparator 32 receives and compares the self-chip address INTCAi and the selected chip address EXTCAi. When the both coincide it sets the output signal “H”, and outputs it to the latch circuit 33. The address alteration detection unit 34 monitors the address EXTCAi selected, and outputs a detection signal to the pulse generation unit 35 when the address EXTCAi selected has changed.

The pulse generation unit 35 outputs a pulse signal to the latch circuit 33 if a detection signal is input from the address alteration detection unit 34.

The latch circuit 33 receives this pulse signal as a trigger signal TRIG, reads the status “H” or “L” of the signal output from the address comparator 32, and outputs it as an address flag signal CAFLG.

Moreover, when the reset signal RST is input to the latch circuit 33, the address flag signal CAFLG is reset to “H”.

Next, an operation of the memory according to the first embodiment will be explained.

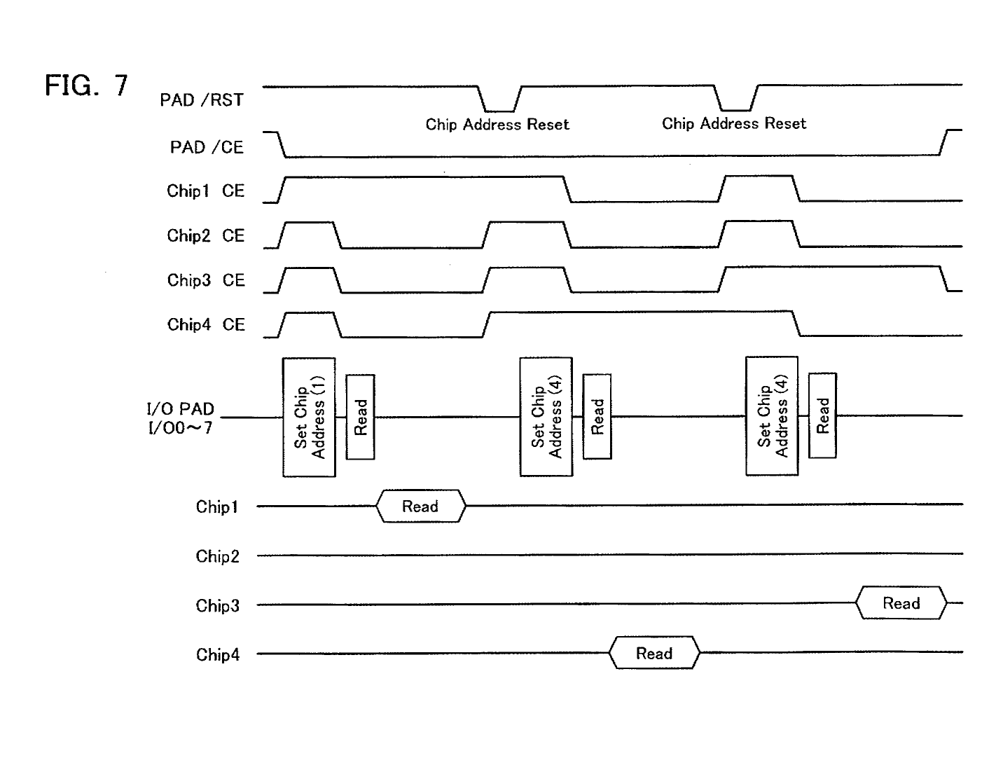

FIG. 7 is a timing chart of the memory according to the first embodiment.

When the reset signal /RST is “H”, and the clip-enable signal /CE is input as “L” from the pads 3 of the uppermost memory chip 2 (Chip1), all the memory chips 2 (Chip 1-4) are once set to a selectable state.

Next, data I/O0-7 is input to all the memory chips 2 (Chip 1-4). This data includes the selected chip address EXTCAi indicating the address of the selected memory chip 2. The selected chip address EXTCAi is latched to the address buffer 17. When the selected chip address EXTCAi is latched, each memory chip 2 uses its chip-address comparator 24 to compare its own self-chip address INTCAi stored in the fuse 23 and the selected chip address EXTCAi to output the address flag signal CAFLG as a matching judgment signal. If the selected chip address EXTCAi specifies Chip1, the address flag signal CAFLG of the chip Chip1 will be “H”. As a result, the chip-enable signal CE′ will be set to “H”. On the other hand, as for the non-selected chips Chip 2-4, the address flag signal CAFLG is set to “L”. As a result, the chip-enable signal CE′ is set to “L.”.

As described above, when one of the memory chip 2 is selected, and the control signal and data I/O 0-7 for data reading are input from the control pad 12 and the I/O pad 11, only the chip Chip1 whose chip-enable signal CE′ is “H” operates, and data in the memory cell array 13 is read only from the chip Chip1. Since the chip-enable signal CE′ is “L”, the buffers 25-30 in the other memory chips Chip 2-4 do not operate, and therefore a read operation is not performed therein.

When a read operation in the memory chip Chip1 is completed, and the reset signal /RST as a reset status “L” is input to the control pad 12, all the memory chips 2 (Chip 1-4) is shifted to a selectable state from a selectable state or a non-selectable state. Then, when the chip address EXTCAi selecting the chip Chip4 is input to each of the memory chip 2 from the control pad 12 and the I/O pad 11, the chip-enable signal CE′ of the chip Chip4 becomes “H”, and the chip-enable signals CE′ of the chips Chip 1-3 not selected are set to “L.”

When the control signals for data reading is input from the control pad 12 and the I/O pad 11 to the chips Chip 1-4, only the chip Chip4 whose chip-enable signal CE′ is “H” operates, and a data reading operation is started therein.

Similarly, when a read operation is completed, and the reset signal /RST as a reset status “L” is input to the control pad 12, all the memory chips Chip 1-4 are shifted to a selectable state from a selectable state or a non-selectable state.

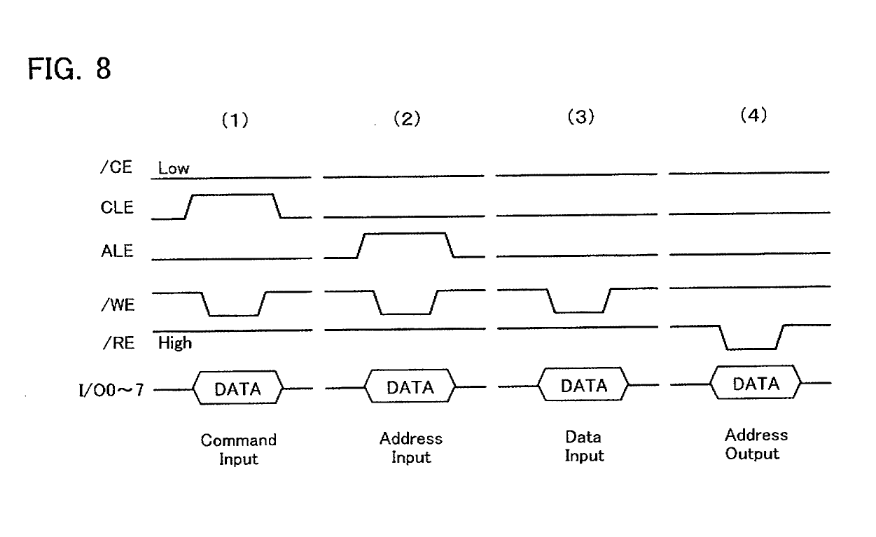

An operation of the memory chip 2 by the control signal input to the control pad 12 thereof will be explained hereinbelow. FIG. 8 is a timing chart that shows an operation of each memory chip 2.

All or any operations of the memory chip such as (1) command input, (2) address input, (3) data input, and (4) data output are performed when the chip-enable signal /CE that permits the access to the memory chip 2 is “L”.

(1) Command Com is input when the chip-enable signal /CE is “L” and the command latch enable signal CLE is “H”. Specifically, when a toggle of the write-enable signal /WE is input in this condition, the data I/O 0-7 will be stored in the command buffer 19 as a command through the I/O buffer 16, and is output to the control circuit 20.
(2) Address Add is input when the chip-enable signal. /CE is “L” and the address-latch-enable signal ALE is “H”. Specifically, when a toggle of the write-enable signal /WE is input in this condition, the data I/O 0-7 will be stored in the address buffer 17 as an address through the I/O buffer 16.
(3) Data is input when the chip-enable signal /CE is “L”, the address-latch-enable signal ALE is “L”, and the command latch enable signal CLE is “L”. Specifically, when a toggle of the write-enable signal /WE is input in this condition, the data I/O 0-7 is input as data. The data I/O 0-7 in a write mode is output to a sense amplifier 15 as an input data through the I/O buffer 16. In a parameter-set mode for changing various setting data such as a timer period in the memory chip, a voltage or the like, the data I/O 0-7 is stored in a latch circuit for the various setting data in the control circuit.

(4) A reading operation is performed by outputting the data stored in the memory cell array 13 to the I/O pad 11 through the I/O buffer 16, when the chip-enable signal /CE is “L”, and the read enable signal /RE is “L”.

Thus, each of the memory chips 2 (Chip 1-4) compares the self-chip address INTCAi with the selected chip address EXTCAi to detect the match therebetween. Then, a control of writing, reading, erasing or the like is performed only in the memory chip 2 in which the self-chip address INTCAi matches the selected chip address EXTCAi. Thereby, a multichip operation of the stacked memory chips with a through via 4 is realized. Moreover, since the pads 3 receiving the respective control signals are commonly connected in the stacked memory chips 2, the number of the pads 3 formed in the uppermost memory chip can be reduced. Accordingly, the memory may be miniaturized.

### Second Embodiment

The memory according to the second embodiment of the present invention will be explained hereinbelow.

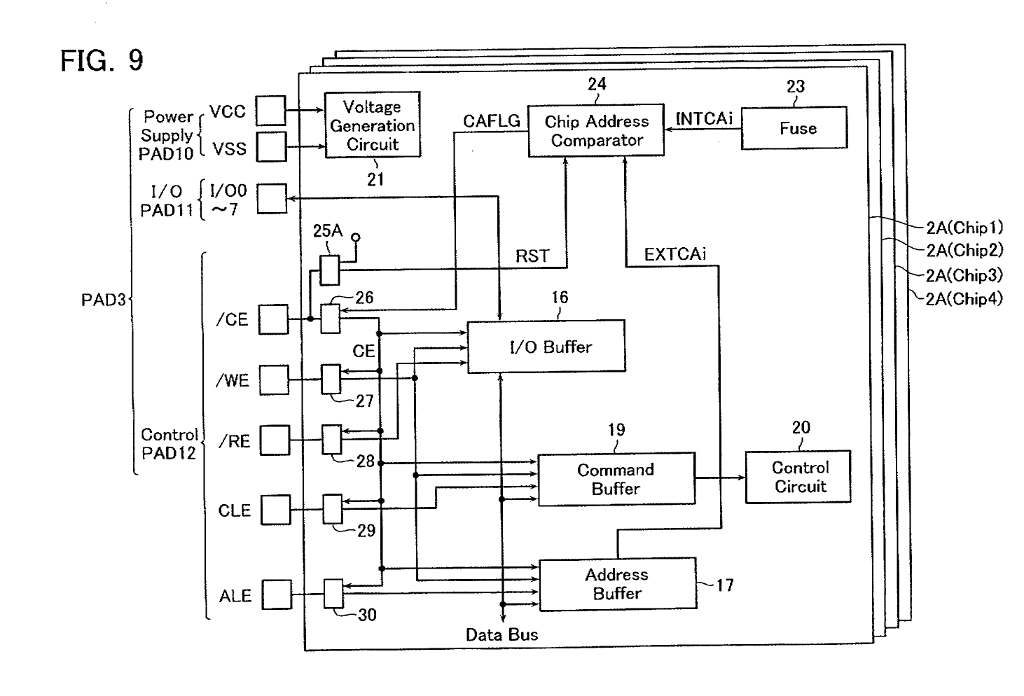

Since the overall configuration of this embodiment is the same as that of the first embodiment as shown in FIG. 1 to FIG. 3, explanation thereof is omitted. FIG. 9 is a block diagram showing the detailed structure of the pads 3 provided in the memory according to the second embodiment, and connections between the pads 3 and the internal circuits in the memory chip 2 in detail.

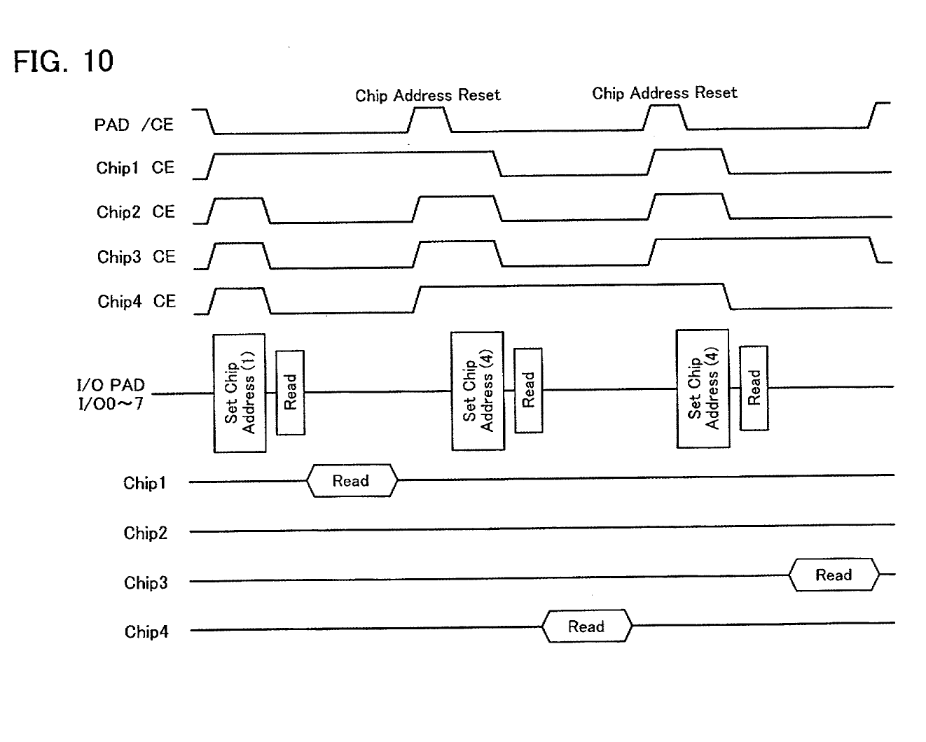

The second embodiment differs from the first embodiment in that the RST buffer 25A provided in the memory chip 2 generates the reset signal RST, without inputting the reset signal /RST through the pad 3. If a chip-enable signal /CE becomes “H”, this RST buffer 25A always outputs the reset signal RST to the chip-address comparator 24. As shown in FIG. 10, the reset signal RST is generated when the logic of the chip-enable signal /CE input from the control pad 12 changes, thereby all the memory chips 2 (Chip 1-4) are shifted to a selectable state from a selectable state or a non-selectable state. Other operations are the same as those of the first embodiment.

In this way, this embodiment generates the reset signal RST based on the switching of the chip-enable signal /CE. Accordingly, the number of the control pads 12 can be reduced, thereby the memory can be further miniaturized.

### Third Embodiment

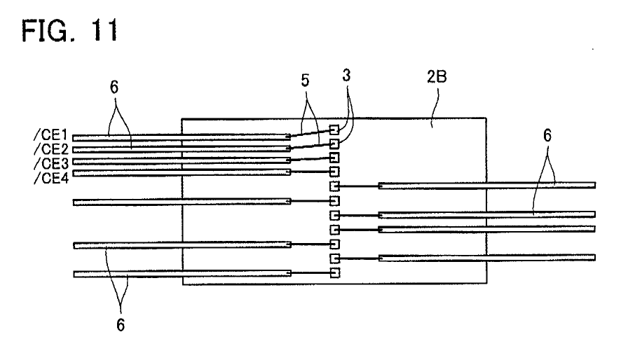

The memory according to the third embodiment of the present invention will be explained hereinbelow. FIG. 11 is a plan view showing the uppermost memory chip 2B of the memory according to the third embodiment. Note that since a sectional view thereof is the same as the first embodiment (FIG. 1), the explanation thereof is omitted.

The third embodiment differs from the first embodiment in that the chip-enable signals /CE1-4 selecting respective memory chips 2B (Chip 1-4) are input from the pad 3 formed in the uppermost memory chip 2, instead of using a chip-address comparator.

The uppermost memory chip 2 has four pads 3 formed thereon, that receive a chip-enable signal /CE 1-4, respectively. These pads 3 are commonly connected to all the memory chips 2B (Chip 1-4) through the through via 4.

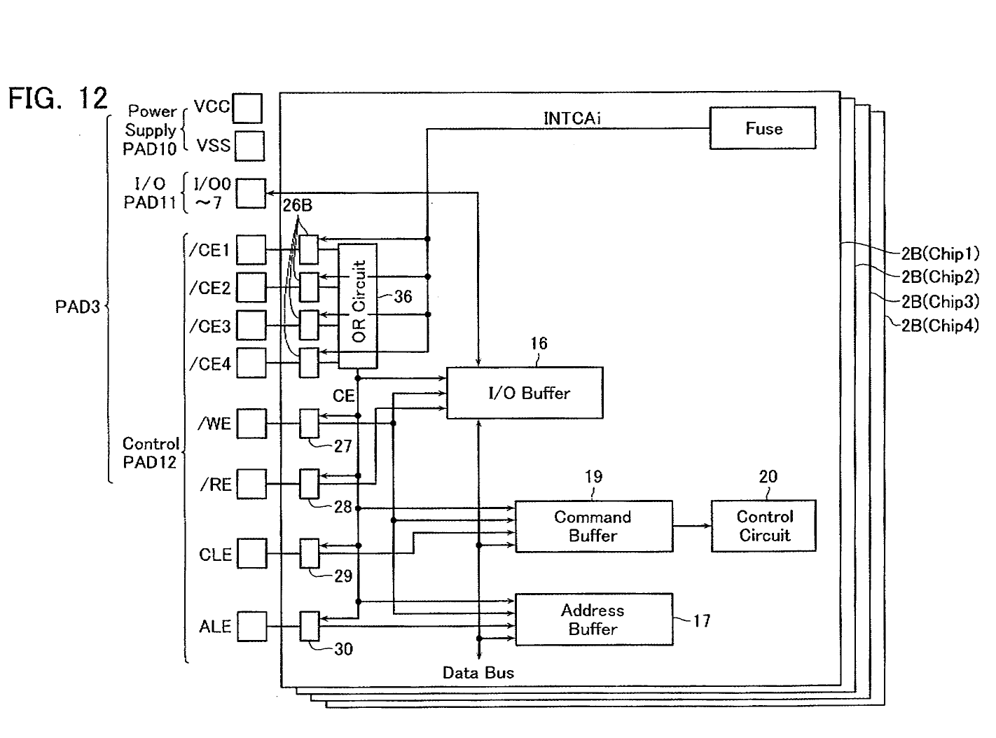

FIG. 12 is a block diagram showing an electric structure of the memory chip included in the memory according to the third embodiment. The four pads 3 that receives a chip-enable signal /CE 1-4 respectively are connected to the CE buffer 26B in each memory chip 2B (Chip 1-4), respectively.

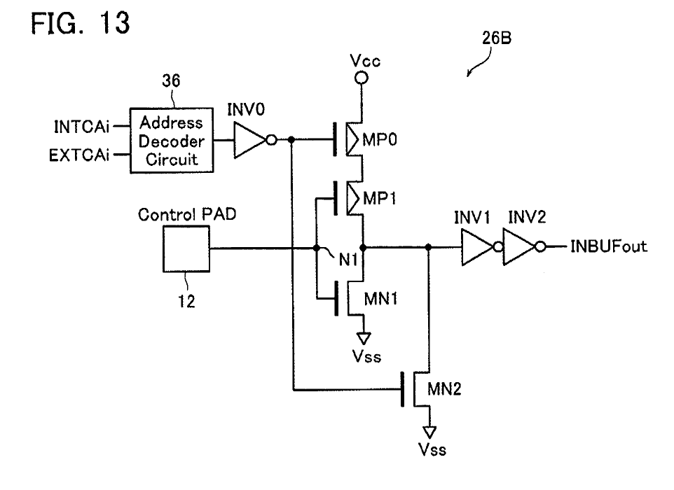

FIG. 13 is a circuit diagram that exemplifies a structure of the CE buffer 26B. The CE buffer 26B comprises a address decoder 36, a P-type MOS transistor MP0, MP1, N-type MOS transistors MN1 and MN2.

The address decoder 36 receives at one of its input terminals the self-chip address INTCAi stored at the fuse 23, and receives the selected chip address EXTCAi at another one of its input terminals. The address decoder 36 detects a match between them, and outputs an address flag signal CAFLG. This address flag signal CAFLG is input to the gate of the P-type MOS transistor MP0 through the inverter INV0 like the first embodiment (FIG. 5). Since other structures are the same as the first embodiment and given the same reference numerals, the detailed explanation thereof is omitted.

In this way, the four CE buffers 26B in each of the memory chips 2B serves as a judgment unit detecting a match between the self-chip address INTCAi and the selected chip address EXTCAi.

As shown in FIG. 12, each of the tour CE buffers 26B configured as described above is connected to one of the input ends of the OR circuit 36. When an address flag signal CAFLG as a signal “H” is input from one of the CE buffers 26B, a chip-enable signal CE′ is output to the WE buffer 27, the RE buffer 28, the CLE buffer 29, and the ALE buffer 30. This makes the control signals input from the control pads 12 become effective.

Thus, by detecting a match between the self-chip address INTCAi and the selected chip address EXTCAi in each of the memory chips 2, multichip operation of the stacked memory chips with a through via 4 is realized. Specifically, a chip address comparator 24 in the first and second embodiments is not necessary.

### Fourth Embodiment

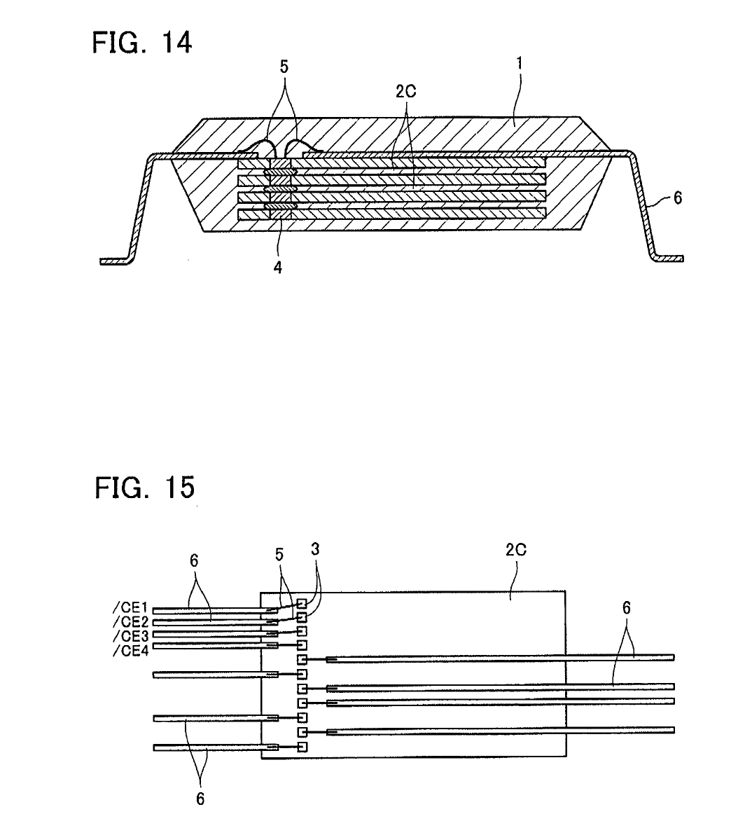

FIG. 14 is a sectional view showing the structure of the memory according to the fourth embodiment of the present invention. Moreover, FIG. 15 is a plan view showing the uppermost memory chip in this memory.

The fourth embodiment differs from the first embodiment in that the pads 3 formed in the uppermost memory chip 2C are formed in the edge of the memory chip 2C. Since the electric structure of this memory is the same as that of the third embodiment, explanation thereof is omitted here. As described above, the pads 3 can be placed anywhere on the plane of the memory chip 2C. This improves the flexibility of memory layout.

Although the above embodiments has been explained using a NAND-type flash memory as an example, the present invention is not limited to these embodiments. The present invention can be applied to any semiconductor memory devices in which a through via commonly connects plural memory chips.

What is claimed is:

1. A semiconductor memory device comprising a plurality of semiconductor chips with commonly-connected I/O pads and control pads for inputting a control signal,
the semiconductor chip comprising:
a self-address storing unit storing a self-chip address showing its own address;
a judgment unit comparing the self-chip address with a selected address provided from outside via the I/O pads to judge a match thereof; and
a control signal setting unit setting the control signal valid or invalid according to the judgment of the match.

2. The semiconductor memory device according to claim 1, wherein
the control signal setting unit sets the control signal valid according to a reset signal.

3. The semiconductor memory device according to claim 2, wherein
the reset signal is input from the control pad as one of the control signals.

4. The semiconductor memory device according to claim 2, further comprising a reset signal generating circuit detecting that a logic of a chip-enable signal for activating the semiconductor chip has been changed to generate the reset signal.

5. The semiconductor memory device according to claim 1, wherein
the self-address storing unit comprises a laser-fuse type fuse element or a nonvolatile memory type fuse element.

6. The semiconductor memory device according to claim 1, wherein
the control signal setting unit comprises a buffer setting the control signal valid or invalid based on a result of the match in the judgment unit.

7. The semiconductor memory device according to claim 6, wherein
the buffer includes:
a first buffer receiving a chip-enable signal for activating the semiconductor chip as the control signal and setting the chip-enable signal valid or invalid based on a result of the match in the judgment unit; and
a second buffer setting the other control signals valid or invalid based on whether the chip-enable signal is valid or invalid.

8. The semiconductor memory device according to claim 1, wherein
the plurality of the semiconductor chips are commonly connected by a through via penetrating from a top layer to a bottom layer.

9. The semiconductor memory device according to claim 1, wherein
the I/0 pads and the control pads are formed in the center of the semiconductor chip in a planar direction.

10. The semiconductor memory device according to claim 1, wherein
the control pads includes a plurality of chip-enable signal input pads for independently inputting plural kinds of chip-enable signals to selectively activate one of the plurality of the semiconductor chips.

11. The semiconductor memory device according to claim 10, further comprising buffers provided corresponding to each of the plural chip-enable signal input pads, and configured to set the chip-enable signal valid when the self-chip address and the selected address matches.

12. The semiconductor memory device according to claim 10, wherein
the control signal setting unit sets the control signal valid according to a reset signal.

13. The semiconductor memory device according to claim 12, wherein
the reset signal is input from the control pads as one of the control signals.

14. The semiconductor memory device according to claim 12, further comprising a reset signal generating circuit detecting that a logic of a chip-enable signal for activating the semiconductor chip has been changed to generate the reset signal.

15. The semiconductor memory device according to claim 1, wherein the I/O pads and a control pads are formed on an edge of the semiconductor chip in a planar direction.

16. The semiconductor memory device according to claim 1, wherein the semiconductor chip comprises a NAND type flash memory.
